(19) United States
(12) Patent Application Publication
(10) Pub. No.: US 2024/0363638 A1
(43) Pub. Date: Oct. 31, 2024

(54) SEMICONDUCTOR CIRCUIT STRUCTURE WITH UNDERGROUND INTERCONNECT (UGI) FOR POWER DELIVERY, POWER MESH, AND SIGNAL DELIVERY

(71) Applicant: Invention and Collaboration Laboratory, Inc., Taipei City (TW)

(72) Inventors: Chao-Chun LU, Hsinchu (TW); Juang-Ying CHUEH, Hsinchu (TW)

(73) Assignee: Invention and Collaboration Laboratory, Inc., Taipei City (TW)

(21) Appl. No.: 18/582,126

(22) Filed: Feb. 20, 2024

Related U.S. Application Data
(60) Provisional application No. 63/461,623, filed on Apr. 25, 2023.

(51) Int. Cl. H01L 27/118; H10B 12/00

(52) U.S. Cl. CPC H01L 27/11807; H10B 12/50; H01L 2027/11881

(57) ABSTRACT

The present invention discloses a semiconductor circuit structure with underground interconnection lines within the semiconductor substrate for signal and power delivery. The semiconductor circuit structure comprises a semiconductor substrate with an original semiconductor surface; a first set of PMOS transistors formed based on the semiconductor substrate, and each PMOS transistor comprising a gate structure, a first conductive region, and a second conductive region; a first shallow trench isolation (STI) region neighboring to the first set of PMOS transistors and extending along a first direction; a first underground interconnection line within the first STI region and positioned under the original semiconductor surface, wherein the first underground interconnection line extends along the first direction, and the first conductive region of each PMOS transistor is electrically connected to the first underground interconnection line; and a first power voltage electrically connected to the first underground interconnection line through a first connecting via.

### CROSS-REFERENCE TO RELATED APPLICATION

This application claims the priority benefit of U.S. provisional application Ser. No. 63/461,623, filed on Apr. 25, 2023. The entirety of the above-mentioned patent application is hereby incorporated by reference herein and made a part of this specification.

### BACKGROUND OF THE INVENTION

### 1. Field of the Invention

The present invention relates to a semiconductor circuit structure, and particularly to a logic circuit with underground interconnection lines within shallow trench isolation regions for power and/or signal delivery.

### 2. Description of the Prior Art

In the state-of-the-art integrated circuits there are many transistors which are connected by conductive interconnections (e.g. Metal wires, polysilicon wires, etc.) to facilitate the signal transfer among the Gate, the Source and the Drain regions (GSD) of these transistors. All these metal wires depend on many contact holes and connection plugs to connect them with GSD, respectively, which causes significant challenges and difficulties with respect to chip-design targets of reducing area, power and noise and increasing performances of integrated circuits especially when the dimensions of integrate circuits on dice must be shrunk significantly owing to demands on scaling device dimensions in order to satisfy Moore's Law. To give an example about concerning on the area penalty: A much larger source or drain diffusion area in contrast to the contact-hole size for connecting metal wires to either Source or Drain must be designed so that the unavoidable photolithographic misalignment due to limitations of lithographic tools should not cause the contact holes to be made outside the underneath edges of source or drain region, respectively. This inevitably increases diffusion areas of transistors and thus die areas, which induces large capacitances to cause significant penalties to the ac performance of circuits, to consume higher power and to add larger noises. How to introduce a better self-aligned contact structure and technology to use the least surface areas for connecting the silicon transistor to its first interconnect metal layer to transmit and receive signals and power is a key challenge for further effective scaling down and improving performance of integrated circuits.

### SUMMARY OF THE INVENTION

The present invention provides a semiconductor logic circuit with underground interconnection lines positioned within the shallow trench isolation (STI) region of the semiconductor substrate for power and/or signal delivery.

An embodiment of the present invention provides a semiconductor circuit structure with underground interconnection lines within the semiconductor substrate for signal and power delivery. The semiconductor circuit structure comprises a semiconductor substrate with an original semiconductor surface; a first set of PMOS transistors formed based on the semiconductor substrate, and each PMOS transistor comprising a gate structure, a first conductive region, and a second conductive region; a first shallow trench isolation (STI) region neighboring to the first set of PMOS transistors and extending along a first direction; a first underground interconnection line within the first STI region and positioned under the original semiconductor surface, wherein the first underground interconnection line extends along the first direction, and the first conductive region of each PMOS transistor is electrically connected to the first underground interconnection line; and a first power voltage electrically connected to the first underground interconnection line through a first connecting via.

According to another aspect of the invention, the first connecting via is extended from the original semiconductor surface to the first underground interconnection line.

According to another aspect of the invention, the first connecting via is extended from a backside surface of the semiconductor substrate to the first underground interconnection line, wherein the backside surface is opposite to the original semiconductor surface.

According to another aspect of the invention, the first conductive region of each PMOS transistor of the first set of PMOS transistors is connected to the first underground interconnection line through a corresponding connecting plug positioned within an active area accommodating the corresponding PMOS transistor.

According to another aspect of the invention, the connecting plug is contacted to a sidewall of the first underground interconnection line.

According to another aspect of the invention, the semiconductor circuit structure further comprises a second set of PMOS transistors formed based on the semiconductor substrate, each PMOS transistor of the second set of PMOS transistors comprising a gate structure, a first conductive region, and a second conductive region; wherein the first conductive region of each PMOS transistor of the second set of PMOS transistors is connected to the first underground interconnection line.

According to another aspect of the invention, the semiconductor circuit structure further comprises a third underground interconnection line under the original semiconductor surface and electrically connected to the first underground interconnection line through a third connecting via, wherein the depth between the top surface of the first underground interconnection line and the original semiconductor surface is different from the depth between the top surface of the third underground interconnection line and the original semiconductor surface.

According to another aspect of the invention, the semiconductor circuit structure further comprises a first set of NMOS transistors formed based on the semiconductor substrate, and each NMOS transistor comprising a gate structure, a first conductive region, and a second conductive region; a second STI region neighboring to the second set of NMOS transistors and extending along the first direction; a second underground interconnection line within the second STI region and positioned under the original semiconductor surface, wherein the second underground interconnection line extends along the first direction, and the second conductive region of each NMOS transistor is connected to the second underground interconnection line; and a second power voltage electrically connected the second underground interconnection line through a second connecting via.

According to another aspect of the invention, the depth between the top surface of the first underground interconnection line and the original semiconductor surface is the same or substantially the same as the depth between the top surface of the second underground interconnection line and the original semiconductor surface.

According to another aspect of the invention, the second connecting via is extended from the original semiconductor surface to the second underground interconnection line.

According to another aspect of the invention, the second connecting via is extended from a backside surface of the semiconductor substrate to the first underground interconnection line, wherein the backside surface is opposite to the original semiconductor surface.

According to another aspect of the invention, the semiconductor circuit structure further comprises a fourth underground interconnection line under the original semiconductor surface and electrically connected to the second underground interconnection line through a fourth connecting via, wherein the depth between the top surface of the second underground interconnection line and the original semiconductor surface is different from the depth between the top surface of the fourth underground interconnection line and the original semiconductor surface.

Another embodiment of the present invention provides semiconductor circuit structure with underground interconnection lines for power gating. The semiconductor circuit structure comprises a semiconductor substrate with an original semiconductor surface; a first set of circuit blocks formed based on the semiconductor substrate; a first shallow trench isolation (STI) extending along the first set of circuit blocks; a first underground interconnection line within the first STI region and positioned under the original semiconductor surface, wherein each circuit block is electrically connected to the first underground interconnection line; a first power source electrically connected to a second underground interconnection line through a first connecting via, wherein the second underground interconnection line is positioned under the original semiconductor surface; and a power gating switch between the first underground interconnection line and the second underground interconnection line, wherein the power gating switch selectively transmits the voltage value of the first power source from the second underground interconnection line to the first underground interconnection line.

According to another aspect of the invention, the first connecting via is extended from the original semiconductor surface to the first underground interconnection line; or the first connecting via is extended from a backside surface of the semiconductor substrate to the first underground interconnection line, wherein the backside surface is opposite to the original semiconductor surface.

According to another aspect of the invention, the depth between the top surface of the first underground interconnection line and the original semiconductor surface is different from the depth between the top surface of the second underground interconnection line and the original semiconductor surface; or the depth between the top surface of the first underground interconnection line and the original semiconductor surface is the same or substantially the same as the depth between the top surface of the second underground interconnection line and the original semiconductor surface.

Another embodiment of the present invention provides a semiconductor circuit structure with underground interconnection line within the semiconductor substrate for common node connection. The semiconductor circuit structure includes a semiconductor substrate with an original semiconductor surface; a first set of circuit blocks formed based on the semiconductor substrate; a first shallow trench isolation (STI) extending along the first set of circuit blocks; a first underground interconnection line within the first STI region and positioned under the original semiconductor surface, wherein one terminal of each circuit block is electrically connected to the first underground interconnection line; and a supply circuit electrically connected to the first underground interconnection line and selectively transmitting a first predetermined signal to the first set of circuit blocks.

According to another aspect of the invention, the supply circuit comprises a first switch between the first underground interconnection line and a first signal generator configured to generate the first predetermined signal, the first signal generator is electrically connected to the first switch through a first connecting via, and the first switch is electrically connected to the first underground interconnection line, wherein the first predetermined signal is selectively transmitted to the first set of circuit blocks through the first switch.

According to another aspect of the invention, the first predetermined signal is a power signal and the first signal generator is a power source.

According to another aspect of the invention, the semiconductor circuit structure further comprises a second supply circuit comprising a second switch between the first underground interconnection line and a second signal generator, the second signal generator is electrically connected to the second switch through a second connecting via, and the second switch is electrically connected to the first underground interconnection line, wherein a second predetermined signal generated by the second signal generator is selectively transmitted to the first set of circuit blocks through the second switch.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1(a) is a top view and Z direction view of layout result of a power distribution network according to an embodiment of the present invention.

FIG. 1(b) is a top view and Z direction view of layout result of a power distribution network according to another embodiment of the present invention.

FIG. 1(c) is a top view and Z direction view of layout result of a power distribution network further according to another embodiment of the present invention.

FIG. 2(a) is diagrams illustrating power gating circuits uses either based on header switch or footer switch to control the current flow into the “Power Gated Block”.

FIG. 2(b) is the cross section view illustrating the conventional power gating structure.

FIG. 2(c) shows the top view of power gating layout structure based on header switch with underground power mesh according to one embodiment of the present invention.

FIG. 3(a) is a diagram illustrating conventional sensing amplifiers array connected to a common node LSLP in DRAM memory.

FIG. 3(b) is a top view of partial layout structure illustrating sensing amplifiers array connected to a common node LSLP through the underground connection line.

### DETAILED DESCRIPTION

The underground interconnection (UGI) line has been proposed in U.S. Pat. No. 11,417,369, and the entirety of the above-mentioned patent is hereby incorporated by reference herein and made a part of this specification. The underground interconnection line is positioned under the original semiconductor surface of the semiconductor substrate. Furthermore, the underground interconnection line can be formed within the STI region and can be connected to the transistor source or drain terminal through a connecting plug within the active area accommodating the transistor. Such connecting plug is connected to a sidewall of the underground interconnection line. The proposed UGI structure within the middle side of the semiconductor substrate can be used for signals or power delivery. The present invention illustrates three examples: power mesh, power gating and common node signal distribution applications.

The possible material of the metal used for Underground interconnection line regarding signal/power delivery could be Tungsten, but due to the sensitivity of Tungsten materials to oxide or oxidation process, it is better that the tungsten layer could be covered by another TiN layer or suitable layer. In this invention, detailed protection process for the tungsten layer is not described, but it is assumed that the metal layers including Tungsten layers are well treated to avoid any oxidation directly over it. Of course, there are some appropriate metal layers suitably used for Underground interconnection lines and word lines rather than be limited a specific type of metal material which is not suitably inserted in the integrated process.

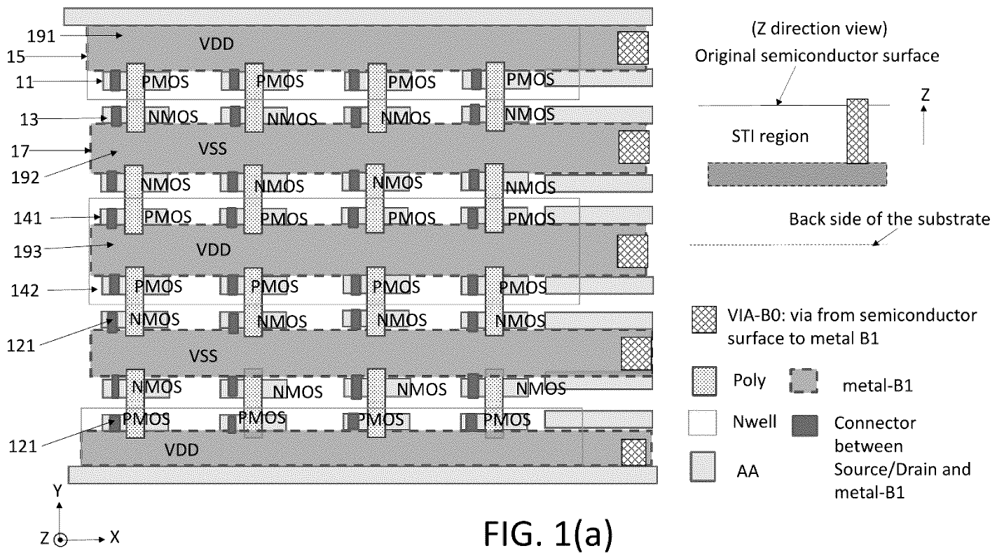

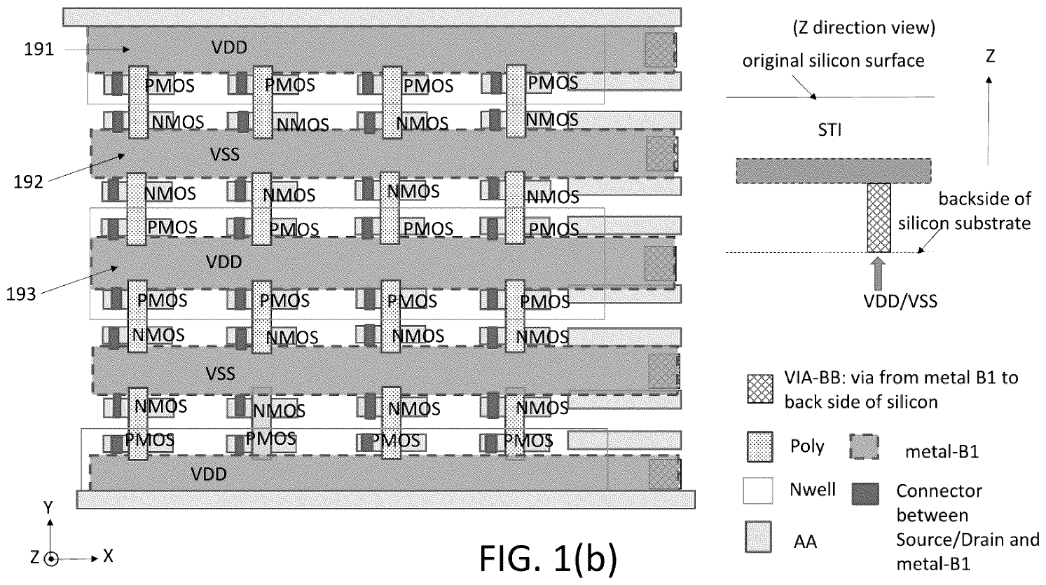

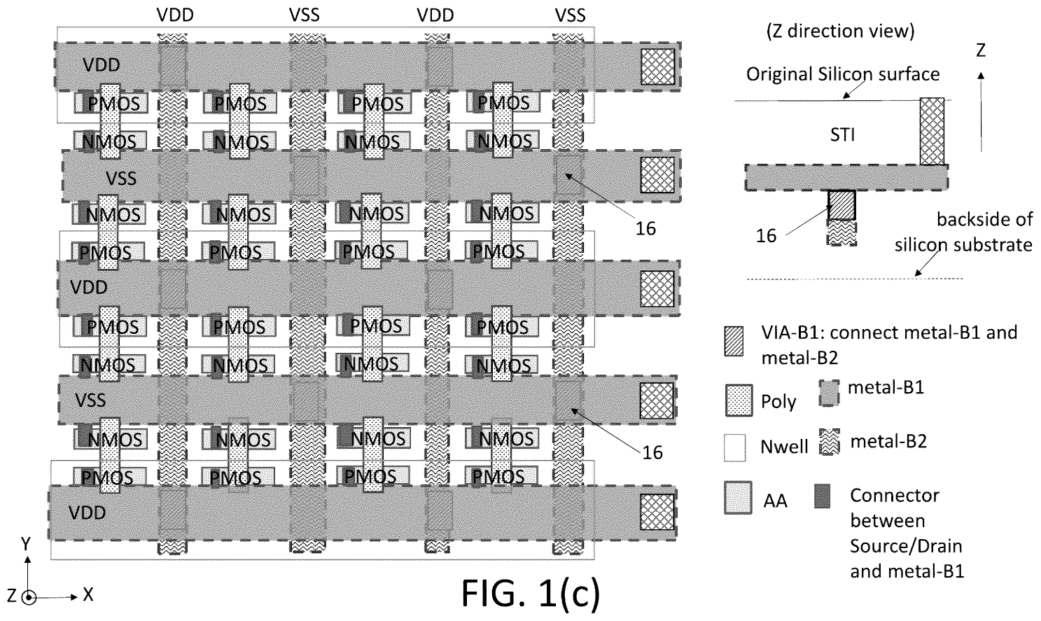

The first example is underground interconnection line is used for power distribution network. Please refer to FIGS. 1(a)˜1(c). In FIG. 1(a), there are PMOS transistors and NMOS transistors formed based on the semiconductor substrate with an original semiconductor surface. The “Nwell” layer stands for N-well region where the PMOS transistor is formed therein. Wherein a set of PMOS transistor 11 are arranged along the x direction, and a set of NMOS transistors 13 are arranged along the x direction as well. The “poly” layer stands for poly gate for the PMOS/NMOS transistor. The “AA” stands for active area where the source or the drain of the PMOS/NMOS transistors is formed. There are shallow trench isolation (STI) region surrounds the active area, for example, there is a first STI region 15 next to the set of the PMOS transistors 11, and the first STI region 15 extends along the x direction. For simplicity, the portion of STI region over the underground interconnection line is not shown in left figures of FIGS. 1(a)˜1(c). Furthermore, there is a second STI region 17 next to the set of NMOS transistors 13, and the second STI region 17 extends along the x direction as well.

The underground interconnection line is named as “metal-B1” and positioned within STI region of the semiconductor substrate, as shown in the Z direction view of FIG. 1(a). For example, a first underground interconnection line 191 is positioned within the first STI region 15 and extends along the x direction, and a second underground interconnection line 192 is positioned within the second STI region 17 and extends along the x direction. “VDD” stands for power signal, and “VSS” stands for ground signal. The VDD signal is applied to the first underground interconnection line 191 and other underground interconnection lines, and The VSS signal is applied to the second underground interconnection line 192 and other underground interconnection lines. In another example, a set of PMOS transistors 141 and a set of PMOS transistors 142 could be connected to the same underground interconnection line 193.

The connecting plug 121 from the underground interconnection line (UGI) to the source/drain terminal of each transistor is formed in the active area of the transistor and represented by “Connector between Source/Drain and metal-B1” in FIG. 1(a). The sidewall of the underground interconnection line under the original semiconductor surface is connected to the connecting plug 121. The connecting plug 121 could be made of highly doped semiconductor material (such as highly doped polysilicon) or metal material (such as Tungsten). In the event when the signals running on the underground interconnection line (“metal-B1” layer) would like to connect to the other signals above the original semiconductor surface, the connecting via “VIA-B0” is formed from the original semiconductor surface to the underground interconnection line, as shown in the Z direction view of FIG. 1(a).

FIG. 1(b) shows the alternative method to use “VIA-BB” to connect the UGI (“metal-B1”) from the backside of semiconductor substrate as shown in FIG. 1(b). The power (VDD) and/or ground (VSS) rails can be supplied in an interleaving way to supply power the transistors from the backside of semiconductor substrate to the underground interconnection lines (such as to the underground interconnection lines 191, 192 and 193). The transistors placement styles illustrated in the FIG. 1(a) or 1(b) is the standard cell placement style widely used in IC design, i.e. from top to bottom, PMOS-NMOS-NMOS-PMOS-PMOS-NMOS-NMOS-PMOS. The underground interconnect is fully compatible with the IC design. In the present invention, the external supply to VDD/VSS can come from front side through VIA-B0 or back side of silicon through VIA-BB. The section under STI region and substrate in modern IC design is under-utilized. The underground interconnect lines are formed within or underneath STI region and within substrate. The underground interconnect lines provide additional layer for signaling or power delivery. In addition, the underground interconnect lines with close proximity to the transistors greatly reduce the resistance and parasitic capacitor of the connection from power or signal wires to transistors.

FIG. 1(c) shows the extension of underground interconnect from one layer (metal-B1) to two layers (“metal-B1” and “metal-B2” in FIG. 1(c)) within different vertical levels of the semiconductor substrate. That is, the depth between the top surface of “metal-B1” layer and the original semiconductor surface of the semiconductor substrate is different from the depth between the top surface of “metal-B2” layer and the original semiconductor surface of the semiconductor substrate. Two underground interconnect layers “metal-B1” and “metal-B2” can be connected by the vias 16 (named as “VIA-B1” in FIG. 1(c)). Although the illustration shows the metal-B1 layer and metal-B2 layer are perpendicular, the metal-B2 layer is not limited to such direction and can be formed in other directions including parallel to the metal-B1 layer. FIG. 1(c) shows the example to form power mesh with two underground interconnect layers. The power mesh can provide a low resistance, low IR drop (electrical current-resistance drop, a.k.a. voltage drop), and low power consumption power supply delivery mechanism to the transistors. In addition, underground power mesh can free up the metal layers originally designated for power delivery. Instead, these metal layers can be utilized for signal routing which will yield a smaller chip size and/or reduce metal layer usages. The external supply to VDD/VSS can come from front side or back side of silicon.

Of course, in another embodiment such “metal-B1” and “metal-B2” layers could be used to transmit other signals rather than the power VDD or VSS.

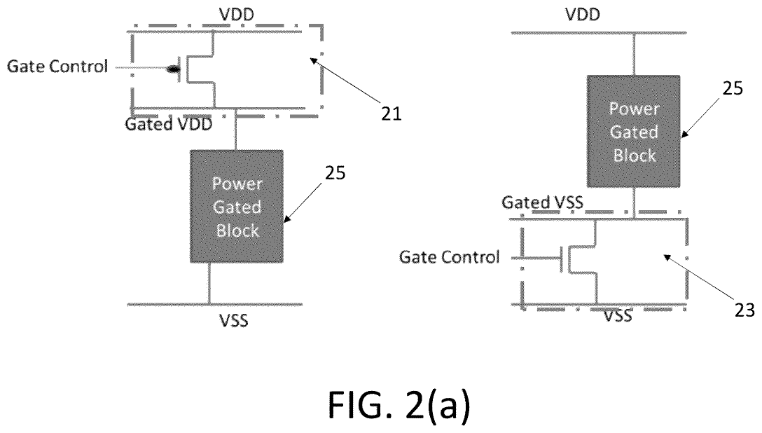

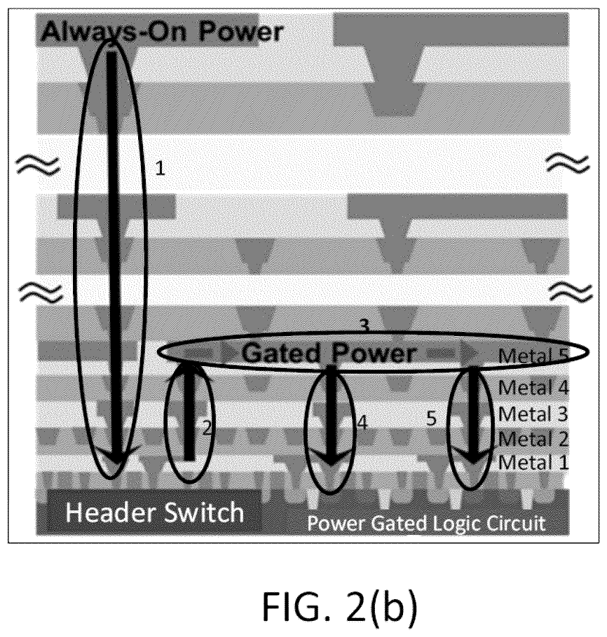

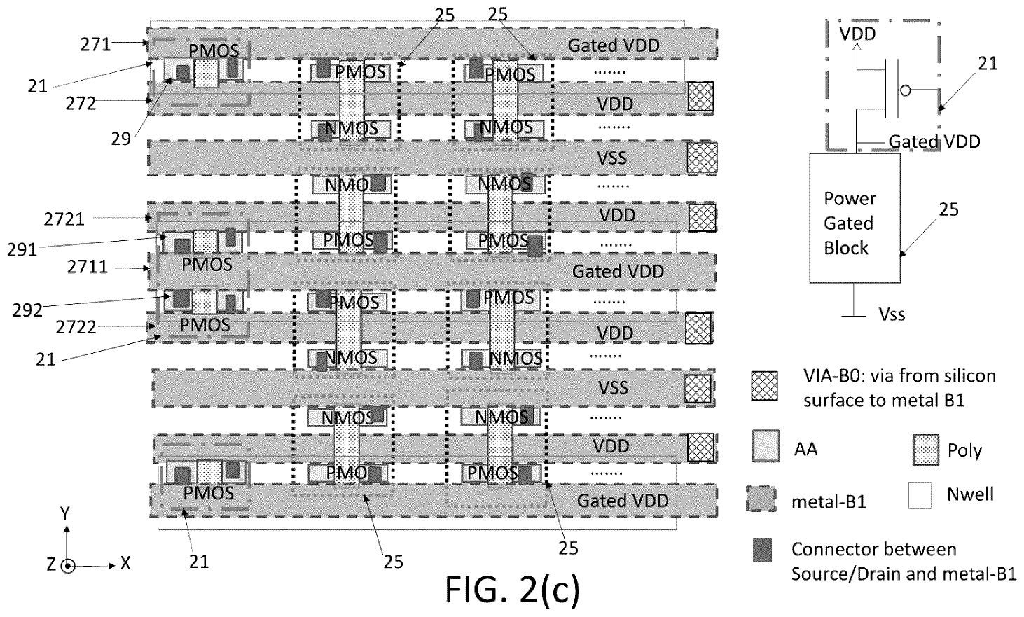

The other embodiment of the present invention regarding the underground interconnect is for power gating methodology. As shown in FIG. 2(a), power gating methodology uses either header switch 21 shown in the left schematics or footer switch 23 in the right schematics to control the current flow into the “Power Gated Block” 25 which may include logic or memory circuits. The header switch 21 (or footer switch 23) may include a transistor playing as a switch to selectively connect the supply VDD voltage to the gated VDD (or connect the VSS voltage to the gated VSS) through the control of the gate control signal. In order to reduce the IR drop between the VDD and gated VDD or IR drop (between the VSS and gated VSS, the underground power rail for power gating application is proposed to supply the power signals to header switches 21 or footer switches 23.

When underground power rail is used in power gating, it yields couple benefits:
It can reduce a lot of vertical and horizontal metal routing resources in the power gating application. Take FIG. 2(b) which is the conventional power gating structure as example, external power supplies power signal from “Always-On Power” node, transferring through metal pieces and via pieces in high-lighted vertical circle 1 in vertical direction to reach to “header switch”. The Gated Power is delivered from “header switch” through high-lighted vertical circle 2 to horizontal Metal 5 layer in high-lighted horizontal circle 3. Through high-lighted vertical circles 4 and 5, the Gated Power is finally delivered to Power Gated Logic Circuit. With UGI used at power gating methodology, all the metal pieces and via pieces in high-lighted blue and green circles can be removed. This will free up metal/via resource originally used for power gating and these metal/via can be used for signal routing and can potentially reduce the metal layer usage and hence reducing chip cost, potentially even reduce chip area as well. The other benefit is to reduce energy consumption when current originally go through these metal and via pieces. Each metal or via contributes some resistance which consumes energy. The resistance incurs IR drop. The underground power rail can reduce the resistance with proximity effect to external power supply.

FIG. 2(c) shows the top views of power gating with underground power mesh. In this example, header switch style power gating methodology is illustrated. Of course, such structure could be applied to footer switch style power gating methodology. VDD (a.k.a. always on power) is connected to the external power supply. The header switches 21 are served as switches to connect between VDD and Gated VDD (a.k.a. gated power). The header switch 21 can control to power up or shut down the power supply to respective “power gated block” 25 by selectively supply the Gated VDD. For simplicity, the portion of STI region over the underground interconnection line is not shown in left figures of FIG. 2(c).

In one embodiment, the header switch 21 includes a PMOS transistor 29 as a switch, and one terminal of the header switch 21 or the transistor 29 is connected to the underground interconnection line 272 which supply VDD. Such VDD signal could be provided from the original semiconductor surface as shown in FIG. 2(c), or could be provided from the backside of the semiconductor substrate, as previously mentioned. The other terminal of the header switch 21 or the transistor 29 is connected to the underground interconnection line 271 for transmitting gated VDD. Through the gate control signal to the PMOS transistor 29, the supply VDD voltage is selectively connected or supplied to the gated VDD. Thus, the PMOS transistors of the respective “power gated block” 25 are connected to the underground interconnection line 271 with gated VDD. In one embodiment, the underground interconnection line 272 and the underground interconnection line 271 could be in the same vertical level of the substrate, or the underground interconnection line 272 and the underground interconnection line 271 could be positioned in different vertical level of the substrate, respectively.

In another embodiment, the header switch 21 may include multiple transistors, such as, a first PMOS transistor 291 and a second PMOS transistor 292. One terminal of the first PMOS transistor 291 is connected to the underground interconnection line 2721 which supply VDD, and the other terminal of the first PMOS transistor 291 is connected to the underground interconnection line 2711 which transmits gated VDD. One terminal of the first PMOS transistor 292 is connected to the underground interconnection line 2722 which supply VDD, and the other terminal of the first PMOS transistor 291 is connected to the same underground interconnection line 2711.

The other embodiment of the present invention regarding the underground interconnection is for signal distribution through a common node. The signal could be data signal (such as, logic “1” or “0”) or power signal (such as, VDD or VSS for power supply) from a signal generator. The common node in circuitry refers to a node extensively interconnected with a plurality of circuit blocks, each circuit could be the same or different, such as logic circuit or DRAM related circuit with transistors or other circuitry. To mitigate resistance along these common nodes, wide or thick metal layers are employed to reduce resistivity. It is evident that these common nodes typically consume a significant portion of metal routing resources. Underground interconnection for common node application can reduces the routing resources for common nodes and potentially can reduce power consumption and event reduce the chip size.

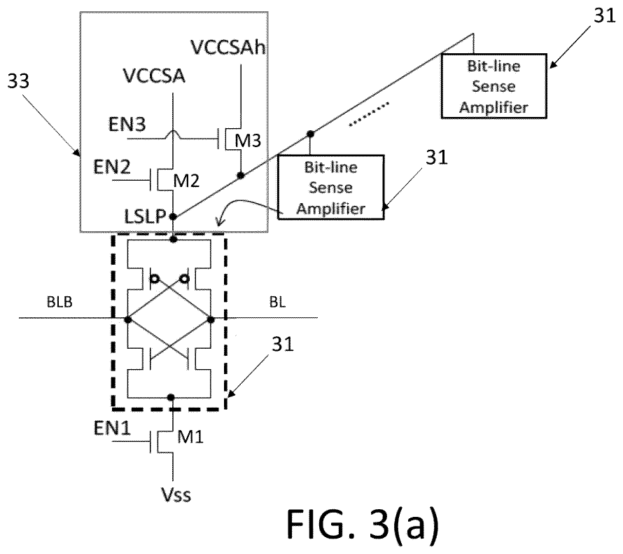

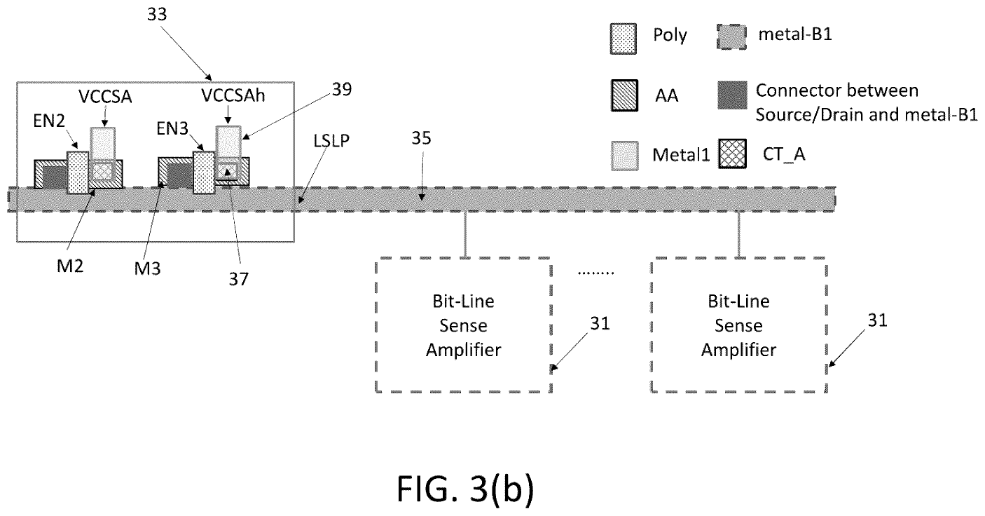

In FIG. 3(a), using sensing amplifiers array in DRAM memory as an example of circuit block, a plurality of bit-line Sense Amplifier circuitries 31 are connected to the “LSLP” point, the LSLP is a common node between Bit-line Sense Amplifier blocks and transistor M2 and transistor M3 of the supply circuit 33 which respectively control the VCCSA voltage signal and VCCSAh voltage signal to the “LSLP” common point through the signals EN2 and EN3. According to the present invention, the top views of the transistors (M2 and M3) and LSLP signal connection using the underground interconnection line 35 (“metal-B1”) are shown in the FIG. 3(b) which is the layout result, wherein VCCSA and VCCSAh power signals are connected through via contact 37 “CT A” and conventional metal 1 layer 39 (“metal 1” or M1) to common node LSLP.

In summary, the invention presents a new architecture of power mesh, power gating and common node signal distribution utilizing underground interconnection lines. Such underground interconnection lines are positioned within the STI region of the semiconductor substrate and connected to the transistors through the connecting plugs in the active area accommodating the transistors. Such underground interconnection lines can reduce a lot of vertical and horizontal metal routing resources in the power gating application, and can reduces the routing resources for common nodes and potentially can reduce power consumption and event reduce the chip size for common node application. Such underground interconnect lines also provide additional layers in the substrate for simplifying signal or power delivery. In addition, the underground interconnect lines with close proximity to the transistors greatly reduce the resistance and parasitic capacitor of the connection from power or signal wires to transistors.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A semiconductor circuit structure comprising:
a semiconductor substrate with an original semiconductor surface;
a first set of PMOS transistors formed based on the semiconductor substrate, and each PMOS transistor comprising a gate structure, a first conductive region, and a second conductive region;
a first shallow trench isolation (STI) region neighboring to the first set of PMOS transistors and extending along a first direction;
a first underground interconnection line within the first STI region and positioned under the original semiconductor surface, wherein the first underground interconnection line extends along the first direction, and the first conductive region of each PMOS transistor is electrically connected to the first underground interconnection line; and
a first power voltage electrically connected to the first underground interconnection line through a first connecting via.

2. The semiconductor circuit structure of claim 1, wherein the first connecting via is extended from the original semiconductor surface to the first underground interconnection line.

3. The semiconductor circuit structure of claim 1, wherein the first connecting via is extended from a backside surface of the semiconductor substrate to the first underground interconnection line, wherein the backside surface is opposite to the original semiconductor surface.

4. The semiconductor circuit structure of claim 1, wherein the first conductive region of each PMOS transistor of the first set of PMOS transistors is connected to the first underground interconnection line through a corresponding connecting plug positioned within an active area accommodating the corresponding PMOS transistor.

5. The semiconductor circuit structure of claim 4, the connecting plug is contacted to a sidewall of the first underground interconnection line.

6. The semiconductor circuit structure of claim 1, further comprising a second set of PMOS transistors formed based on the semiconductor substrate, each PMOS transistor of the second set of PMOS transistors comprising a gate structure, a first conductive region, and a second conductive region; wherein the first conductive region of each PMOS transistor of the second set of PMOS transistors is connected to the first underground interconnection line.

7. The semiconductor circuit structure of claim 1, further comprising a third underground interconnection line under the original semiconductor surface and electrically connected to the first underground interconnection line through a third connecting via, wherein the depth between the top surface of the first underground interconnection line and the original semiconductor surface is different from the depth between the top surface of the third underground interconnection line and the original semiconductor surface.

8. The semiconductor circuit structure of claim 1, further comprising:
a first set of NMOS transistors formed based on the semiconductor substrate, and each NMOS transistor comprising a gate structure, a first conductive region, and a second conductive region;
a second STI region neighboring to the second set of NMOS transistors and extending along the first direction;
a second underground interconnection line within the second STI region and positioned under the original semiconductor surface, wherein the second underground interconnection line extends along the first direction, and the second conductive region of each NMOS transistor is connected to the second underground interconnection line; and
a second power voltage electrically connected to the second underground interconnection line through a second connecting via.

9. The semiconductor circuit structure of claim 8, wherein the depth between the top surface of the first underground interconnection line and the original semiconductor surface is the same or substantially the same as the depth between the top surface of the second underground interconnection line and the original semiconductor surface.

10. The semiconductor circuit structure of claim 8, wherein the second connecting via is extended from the original semiconductor surface to the second underground interconnection line.

11. The semiconductor circuit structure of claim 8, wherein the second connecting via is extended from a backside surface of the semiconductor substrate to the first underground interconnection line, wherein the backside surface is opposite to the original semiconductor surface.

12. The semiconductor circuit structure of claim 8, further comprising a fourth underground interconnection line under the original semiconductor surface and electrically connected to the second underground interconnection line through a fourth connecting via, wherein the depth between the top surface of the second underground interconnection line and the original semiconductor surface is different from the depth between the top surface of the fourth underground interconnection line and the original semiconductor surface.

13. A semiconductor circuit structure comprising:
a semiconductor substrate with an original semiconductor surface;
a first set of circuit blocks formed based on the semiconductor substrate;
a first shallow trench isolation (STI) extending along the first set of circuit blocks;
a first underground interconnection line within the first STI region and positioned under the original semiconductor surface, wherein each circuit block is electrically connected to the first underground interconnection line;
a first power source electrically connected to a second underground interconnection line through a first connecting via, wherein the second underground interconnection line is positioned under the original semiconductor surface; and
a power gating switch between the first underground interconnection line and the second underground interconnection line, wherein the power gating switch selectively transmits the voltage value of the first power source from the second underground interconnection line to the first underground interconnection line.

14. The semiconductor circuit structure of claim 13, wherein the first connecting via is extended from the original semiconductor surface to the first underground interconnection line; or the first connecting via is extended from a backside surface of the semiconductor substrate to the first underground interconnection line, wherein the backside surface is opposite to the original semiconductor surface.

15. The semiconductor circuit structure of claim 13, wherein the depth between the top surface of the first underground interconnection line and the original semiconductor surface is different from the depth between the top surface of the second underground interconnection line and the original semiconductor surface; or the depth between the top surface of the first underground interconnection line and the original semiconductor surface is the same or substantially the same as the depth between the top surface of the second underground interconnection line and the original semiconductor surface.

16. A semiconductor circuit structure comprising:
a semiconductor substrate with an original semiconductor surface;
a first set of circuit blocks formed based on the semiconductor substrate;
a first shallow trench isolation (STI) extending along the first set of circuit blocks;
a first underground interconnection line within the first STI region and positioned under the original semiconductor surface, wherein one terminal of each circuit block is electrically connected to the first underground interconnection line; and
a supply circuit electrically connected to the first underground interconnection line and selectively transmitting a first predetermined signal to the first set of circuit blocks.

17. The semiconductor circuit structure of claim 16, wherein the supply circuit comprises a first switch between the first underground interconnection line and a first signal generator configured to generate the first predetermined signal, the first signal generator is electrically connected to the first switch through a first connecting via, and the first switch is electrically connected to the first underground interconnection line, wherein the first predetermined signal is selectively transmitted to the first set of circuit blocks through the first switch.

18. The semiconductor circuit structure of claim 16, wherein the first predetermined signal is a power signal and the first signal generator is a power source.

19. The semiconductor circuit structure of claim 16, further comprising:
a second supply circuit comprising a second switch between the first underground interconnection line and a second signal generator, the second signal generator is electrically connected to the second switch through a second connecting via, and the second switch is electrically connected to the first underground interconnection line, wherein a second predetermined signal generated by the second signal generator is selectively transmitted to the first set of circuit blocks through the second switch.
